(19) United States
(12) Patent Application Publication
(10) Pub. No.: US 2009/0139753 A1
(43) Pub. Date: Jun. 4, 2009

(54) Copper Clad Laminate for Chip on Film

(75) Inventors: Byung-Nam Kim, Seoul (KR); Heon-Sik Song, Daejeon Metropolitan City (KR); Soon-Yong Park, Daejeon Metropolitan City (KR); Jung-Jin Shim, Gyeongsangbuk-do (KR)

Correspondence Address: MCKENNA LONG & ALDRIDGE LLP, 1900 K STREET, NW, WASHINGTON, DC, 20006, US

(73) Assignee: LG CHEM, LTD., Seoul (KR)

(21) Appl. No.: 12/084,545

(22) PCT Filed: Feb. 5, 2007
(86) PCT No.: PCT/KR2007/000609

§ 371 Date: May 5, 2008

(30) Foreign Application Priority Data
Feb. 6, 2006 (KR) 10-2006-0011327

(51) Int. Cl. H05K 1/09; B32B 15/08; H05K 3/00

(52) U.S. Cl. 174/257; 428/447; 428/339; 427/97.6

(57) ABSTRACT

The present invention relates to a copper clad laminate for chip on film, specifically to a copper clad laminate for a chip on film comprising a copper clad and at least one polyimide layer laminated on the copper clad, wherein the polyimide layer in contact with the copper clad comprises at least one additive selected from the group consisting of an azole-based compound, a polysiloxane-based compound, and a polyphosphate-based compound. The copper clad laminate for a chip on a film according to the present invention, upon tin plating the copper clad at high temperature, prevents delamination between the copper clad and the polyimide layer, and has excellent adhesiveness under the temperature and pressure on IC chip bonding.

### TECHNICAL FIELD

The present invention relates to a copper clad laminate for a chip on a film, specifically to a copper clad laminate for a chip on film comprising a copper clad and at least one polyimide layer laminated on the copper clad, wherein the polyimide layer in contact with the copper clad comprises at least one additive selected from the group consisting of an azole-based compound, a polysiloxane-based compound, and a polyphosphate-based compound.

This application claims priority from Korean Patent Application No. 10-2006-0011327 filed on Feb. 6, 2006 in the Korean Intellectual Property Office, the disclosure of which is incorporated herein by reference in its entirety.

### BACKGROUND ART

The copper clad laminate (CCL) for a chip on a film (COF) used for the large display board in the conventional printed circuit boards is produced by tin (Sn) plating Cu leads on tape and the gold bump on IC chip and attaching by heat, in order to attach IC chip (integrated circuit chip) to a chip assembly maker. The copper clad laminate is produced by a sputtering type or a casting type.

In the case of a sputtering type, there is the problem that a high temperature (higher than 400° C.) and pressure applied upon attaching by heat cause the delamination between the copper clad and the polyimide layer, plating solution penetrating thereto, and deteriorating its appearance.

Further, in the case of a casting type, a polyimide layer with excellent thermoplasticity was used as a polyimide layer in contact with a copper clad, in order to prevent IL (inner lead) sink on IC chip bonding under high temperature. The thermoplastic polyimide is flexible to improve its adhesiveness significantly. However, there is the problem that the polyimide layer presses down the copper clad patterns on printed circuit (see FIG. 1). Accordingly, in order to solve the problems, a thermoplastic polyimide is replaced with a thermosetting polyimide. A thermosetting polyimide is hard and does not press down the copper patterns on printed circuit. However, there is the problem that its adhesiveness is significantly deteriorated. Generally, on IC chip bonding, the pressure is applied with 10 to 15 Kg, for 1 second.

Due to the above problems, adhesiveness of the copper clad laminate for a chip on a film is deteriorated at high temperature (higher than 400° C.).

### DISCLOSURE OF INVENTION

### Technical Solution

The present inventors have studied a copper clad laminate for a chip on a film which has excellent adhesiveness at high temperature. The inventors confirmed that a polyimide comprising at least one additive selected from the group consisting of an azole-based compound, a polysiloxane-based compound, and a polyphosphate-based compound is laminated on a copper clad as a base layer, which prevents the delamination between the copper clad and the polyimide layer, and improves adhesiveness upon tin plating the copper clad at a high temperature. And finally, they completed the present invention.

The present invention provides a copper clad laminate for a chip on a film which has excellent adhesiveness at high temperature.

Further, the present invention provides a method of producing the copper clad laminate for a chip on a film.

Furthermore, the present invention provides a printed circuit board comprising the copper clad laminate for a chip on a film.

### ADVANTAGEOUS EFFECTS

In the copper clad laminate for a chip on a film according to the present invention, the copper clad is laminated with a polyimide layer as a base layer comprising at least one additive selected from the group consisting of an azole-based compound, a polysiloxane-based compound, and a polyphosphate-based compound. Accordingly, upon tin plating the copper clad and bonding IC chip and the tin plated copper clad, delamination between the copper clad, and the polyimide layer can be prevented, and adhesiveness is improved at high temperature.

### BRIEF DESCRIPTION OF THE DRAWINGS

FIG. 1 illustrates a bonding process of a conventional copper clad laminate in IC chip.

FIG. 2 illustrates the cross section of the copper clad laminate according to present invention.

FIG. 3 describes adhesiveness of the copper clad laminate according to present invention.

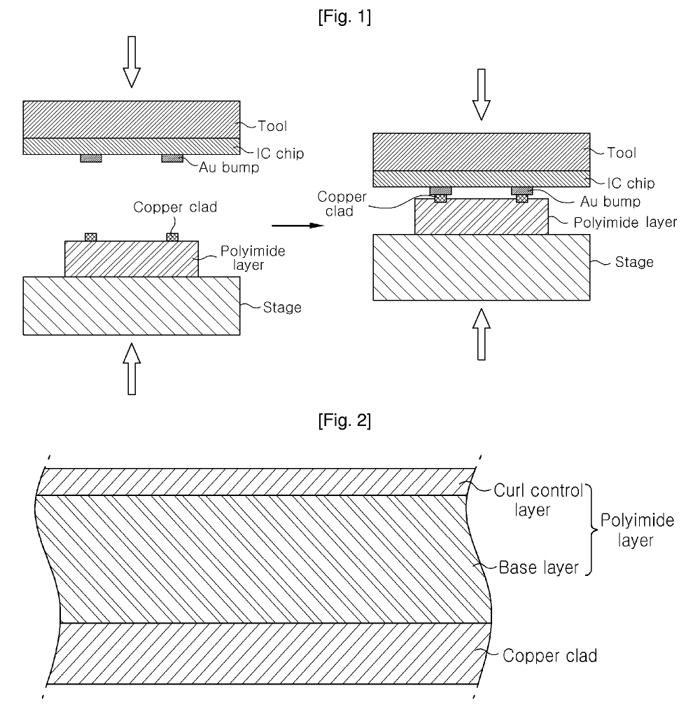

### BEST MODE FOR CARRYING OUT THE INVENTION

The present invention provides a copper clad laminate for a chip on film comprising a copper clad and at least one polyimide layer laminated on the copper clad, wherein the polyimide layer in contact with the copper clad comprises at least one additive selected from the group consisting of an azole-based compound, a polysiloxane-based compound, and a polyphosphate-based compound.

Further, the present invention provides a method of producing the copper clad laminate for a chip on a film.

Furthermore, the present invention provides a printed circuit board comprising the copper clad laminate for a chip on a film.

Hereinbelow, the present invention will be described in detail.

In the copper clad laminate in the invention, a polyimide layer in contact with a copper clad is characterized in comprising at least one compound selected from the group consisting of an azole-based compound, a polysiloxane-based compound, and a polyphosphate-based compound.

The polyimide used in the invention can be prepared by the method that is known in the art, with a diamine and a dianhydride, but not limited thereto.

In the preparation a polyimide in the invention, examples of the diamine compound may include at least one compound selected from the group consisting of para-phenylene diamine (p-PDA), m-phenylene diamine (m-PDA), 4,4′-oxydianiline (4,4′-ODA), 3,4′-oxydianiline (3,4′-ODA), 2,2-bis(4-[4-aminophenoxy]-phenyl) propane (BAPP), 2,2′-Dimethyl-4,4′-diamino biphenyl (m-TB-HG), 1,3-bis (4-aminophenoxy)benzene (TPER), 4,4′-diamino benzanilide (DABA), and 4,4′-bis (4-aminophenoxy)biphenyl (BAPB).

In the preparation of a polyimide in the invention, examples of the dianhydride compound may include at least one compound selected from the group consisting of pyromellitic dianhydride (PMDA), 3,3′,4,4′-biphenyltetracarboxylic dianhydride (BPDA), 3,3′,4,4′-benzophenonetetracarboxilic dianhydride (BTDA), and 4,4′-oxydiphthalic anhydride (ODPA).

In the invention, a small amount of other diamine, other dianhydride, or other compounds than the above compounds can be added, if desired.

In the preparation of a polyamic acid as a polyimide precursor in the invention, examples of the preferable organic solvent may include at least one compound selected from the group consisting of N-methyl-2-pyrrolidone (NMP), N,N-dimethyl acetamide (DMAc), N,N-dimethylformamide (DMA), tetrahydrofuran (THF), N,N-dimethylformamide (DMF), dimethyl sulfoxide (DMSO), cyclohexane, acetonitrile, and the mixture thereof, but not limited thereto.

It is preferable that the polyamic acid is 10 to 30% by weight in total solution. If the content of the polyamic acid is less than 10% by weight, an unnecessary solvent has to be used. If the content of the polyamic acid is more than 30% by weight, the solution viscosity is too high to coat evenly.

The polyamic acid solution can be prepared as a random copolymer or a block copolymer. The reaction temperature is preferably in the range of 0 to 100° C. The viscosity of a polyamic acid solution is preferably 2,000 to 50,000 cps in the process of producing a copper clad laminate.

The azole-based compound as an additive functions as an anti-oxidant, as well as improves adhesiveness. Specific examples thereof include 3,5-diamino-1,2,4-triazole, 3-amino-1,2,4-triazole, 5-amino-1,2,4-triazole-5-carboxylic acid, 3-amino-5-mercapto-1,2,4-triazole, 5-amino-1H-tetrazole, 3-mercapto-1,2,4-triazole, 5-phenyl-1H-tetrazole, and 2-hydroxy-n-1H-1,2,4-triazole-3-ylbenzamide (ADK). It is preferable that the azole-based compound having an amine group has a content of 1.5 to 5 mol % based on the total of diamine and dianhydride. It is preferable that the azole-based compound not having an amine group has a content of 0.5 to 5% by weight, based on the total weight of solid polyamic acid. In the case where the azole-based compound having an amine group has a content of less than 1.5 mol % or where the azole-based compound not having an amine group has a content of less than 0.5% by weight, it is hard to exhibit adhesiveness at room temperature and high temperature. In the case where the azole-based compound having an amine group has a content of more than 5 mol % or where the azole-based compound not having an amine group has a content of more than 5% by weight, there is a chance that the basic properties of the polyimide could be changed.

The polysiloxane-based compound or the polyphosphate-based compound as additives has excellent heat resistance. Examples of the polysiloxane-based compound include a hydroxy terminated poly(dimethylsiloxane) (molecular weight: 500 to 3,000) and a hydroxy terminated poly(dimethylsiloxane) (molecular weight: 3,000 to 10,000). Further, examples of the polyphosphate-based compound include a polyphosphoric acid (H₃PO₄; containing P₂O₅ of 70 to 71% by weight or more in phosphoric acid), a polyphosphoric acid (H₃PO₄; containing P₂O₅ of 82.5 to 83.5% by weight or more in phosphoric acid). It is preferable that the polysiloxane-based compound or the polyphosphate-based compound has a content of 0.5 to 5% by weight respectively, based on the total weight of solid polyamic acid. In the case where the polysiloxane-based compound has a content of more than 5% by weight, there is no change in its adhesiveness. In the case where the polyphosphate-based compound has a content of more than 5% by weight, the polyphosphate-based compound may corrode the copper clad due to its corrosiveness.

The polyimide in the invention may further include additives such as an antifoaming agent, an antigelling agent, and a curing accelerator, in order to make c oating or curing easy and to improve other properties.

Further, the present invention provides a method of producing the copper clad laminate for chip on film, comprising the steps of;

1) coating a polyamic acid solution on each or both sides of a copper clad, wherein the polyamic acid solution comprises at least one additive selected from the group consisting of an azole-based compound, a polysiloxane-based compound, and a polyphosphate-based compound, and drying it, and

2) coating a polyamic acid solution on each or both sides of the copper clad dried in the step of 1), wherein the polyamic acid solution does not comprise one or more additive selected from the group consisting of an azole-based compound, a polysiloxane-based compound, and a polyphosphate-based compound, drying it, and then curing it.

In the step of 1), upon the copper clad coating with the polyamic acid solution, a die coater, a comma coater, a reverse comma coater, a gravure coater, or the like can be used. Conventional coaters other than the above-coaters may be used. The coating temperature depends on the structure or condition of an oven, upon drying the polyamic acid solution. The coating temperature is preferably 50 to 350° C., which is lower than the general boiling point of solvents, more preferably 80 to 250° C.

In the step of 2), each or both sides of the dried copper clad is coated with the polyamic acid solution not comprising one or more additive selected from the group consisting of an azole-based compound, a polysiloxane-based compound, and a polyphosphate-based compound, and dried to cure with heating up to 390° C. The curing can be performed with heating gradually under nitrogen atmosphere or vacuum, or with introducing high heat successively under nitrogen atmosphere.

As such, a copper clad laminate for a chip on a film having polyimide layer without bubbles can be produced by the present invention.

In the copper clad laminate for a chip on a film according to the invention, it is characterized in that a polyimide layer is composed of a base layer and a curl control layer, and the base layer is the polyimide layer in contact with a copper clad (FIG. 2).

According to the invention, the copper clad laminate for a chip on film comprises the polyimide layer as a base layer which is laminated on a copper clad, wherein the polyimide layer in contact with the copper clad comprises at least one additive selected from the group consisting of an azole-based compound, a polysiloxane-based compound, and a polyphosphate-based compound. Subsequently, upon tin plating the copper clad at high temperature, the delamination between the copper clad and the polyimide layer can be prevented, and adhesiveness can be improved.

A polyimide layer not comprising at least one compound selected from the group consisting of an azole-based compound, a polysiloxane-based compound, and a polyphosphate-based compound is laminated on the base layer, to achieve curl control.

In the copper clad laminate according to the invention, the polyimide layer constituted with a base layer and a curl control layer has preferably a thickness of 30 to 50 □. Among these, it is preferable that the base layer has a thickness of 80% or more, based on the total thickness of the polyimide layer.

Further, the invention provides a printed circuit board comprising the copper clad laminate for a chip on a film.

The printed circuit board can be produced by the method which is conventional in the related art, except comprising the copper clad laminate for a chip on a film according to the invention.

### MODE FOR THE INVENTION

Hereinafter, preferable Examples are provided for the purpose of making the present invention more understandable. As such, Examples are provided for illustrating the Examples, but the scope of the invention is not limited thereto.

### PREPARATIVE EXAMPLE 1

5.65 g of para-phenylene diamine (p-PDA) and 0.27 g of 3,5-diamino-1,2,4-triazole were dissolved in 162 □ of N-methylpyrrolidinon. To the solution, 8.09 g of 3,3′,4,4′-biphenyltetracarboxylic dianhydride (BPDA) and 6.00 g of pyromellitic dianhydride (PMDA) were added, and polymerized with stirring for 24 hours. At this time, the polymerization temperature is 5° C., and a polyamic acid was prepared as a polyimide precursor.

### PREPARATIVE EXAMPLE 2 to 16

A polyamic acid as a polyimide precursor was prepared in the same manner as in Preparative Example 1, with the same compositions and ratios as shown in table 1.

TABLE 1

| | Dianhydride (g) | | Diamine (g) | | |
|---|---|---|---|---|---|
| | BPDA | PMDA | p-PDA | 4,4′-ODA | Additive (g) |
| Preparative | 8.09 | 6.00 | 5.65 | — | Triazole |
| Example 1 | | | | | compound |
| | | | | | 0.27 |
| Preparative | 7.88 | 5.84 | 5.21 | 1.07 | — |
| Example 2 | | | | | |
| Preparative | 8.08 | 5.99 | 5.76 | — | Triazole |
| Example 3 | | | | | compound |
| | | | | | 0.16 |
| Preparative | 8.03 | 5.99 | 5.82 | — | Triazole |
| Example 4 | | | | | compound |
| | | | | | 0.11 |
| Preparative | 8.08 | 5.99 | 5.94 | — | ADK |
| Example 5 | | | | | 0.10 |
| Preparative | 13.04 | — | 5.94 | — | ADK |
| Example 6 | | | | | 0.06 |
| Preparative | 8.08 | 5.99 | 5.94 | — | A-type |
| Example 7 | | | | | 0.10 |
| Preparative | 8.08 | 5.99 | 5.94 | — | A-type |
| Example 8 | | | | | 0.06 |
| Preparative | 8.08 | 5.99 | 5.94 | — | B-type |
| Example 9 | | | | | 0.10 |
| Preparative | 8.08 | 5.99 | 5.94 | — | B-type |
| Example 10 | | | | | 0.06 |
| Preparative | 7.17 | 5.32 | 2.63 | 4.88 | — |
| Example 11 | | | | | |
| Preparative | 8.08 | 5.99 | 5.94 | — | C-type |
| Example 12 | | | | | 0.10 |
| Preparative | 8.08 | 5.99 | 5.94 | — | C-type |
| Example 13 | | | | | 0.06 |
| Preparative | 8.08 | 5.99 | 5.94 | — | D-type |
| Example 14 | | | | | 0.10 |
| Preparative | 8.08 | 5.99 | 5.94 | — | D-type |
| Example 15 | | | | | 0.06 |
| Preparative | 7.13 | 5.29 | 2.63 | 4.88 | — |
| Example 16 | | | | | |

 BPDA: 3,3′,4,4′-Biphenyltetracarboxylic dianhydride,
PMDA: Pyromellitic dianhydride,
p-PDA: Para-phenylene diamine,
4,4′-ODA: 4,4′-Oxydianiline,
Triazole compound: 3,5-Diamino-1,2,4-triazole,
ADK: 2-Hydroxy-n-1H-1,2,4-triazole-3-ylbenzamide,
A-type: Hydroxy terminated poly (dimethylsiloxane) (molecular weight: 500 to 3,000, Aldrich catalog No. 48, 193-9),
B-type: Polyphosphoric acid (H₃PO₄; containing P₂O₅ of 70 to 71% by weight or more in phosphoric acid),
C-type: Hydroxy terminated Poly (dimethylsiloxane) (molecular weight 3,000 to 10,000, CAS No. 156327-07-0),
D-type: Polyphosphoric acid (H₃PO₄; containing P₂O₅ of 82.5 to 83.5% by weight or more in phosphoric acid).

### EXAMPLE 1

### Copper Clad Laminate Construction

The copper clad was coated with the polyamic acid solution prepared in Preparative Example 1, and then cured to have a thickness of 32 □. Thereafter, the resultant was dried at 140° C., and the copper clad was coated with the polyamic acid solution prepared in Preparative Example 11 in the same manner for contacting the clad with the solution, and then cured to have a thickness of 8 □. The copper clad is subjected to curing with heating to 350° C.

The copper clad laminate was cut to a size of 25 □ by 25 □, and the presence of bubbles on the surface of the polyimide layer was examined. In the case where the number of bubble on the surface of the polyimide layer is 0, it was concluded that no bubble was generated.

No bubble was generated on the surface of the cured polyimide layer.

### EXAMPLES 2 TO 7 AND COMPARATIVE EXAMPLES 1 TO 8

A copper clad laminate was produced using the polyamic acid prepared in Preparative Example 2 to 16, in the same manner as in Example 1. Further, the presence of bubbles on the surface of the polyimide layer was examined.

In the copper clad laminate, the polyamic acid, the thickness of the polyimide layer, and the presence of bubbles of the polyimide layer are shown in table 2 as follows.

TABLE 2

| | Polyimide layer | | Polyimide layer | | |
|---|---|---|---|---|---|
| | (Base layer) | | (Curl control layer) | | |
| | | Thick- | | Thick- | |
| | Polyamic | ness | Polyamic | ness | |
| | acid solution | (μm) | acid solution | (μm) | Bubble |
| Example 1 | Preparative | 32 | Preparative | 8 | None |
| | Example 1 | | Example 11 | | |
| Example 2 | Preparative | 32 | Preparative | 8 | None |
| | Example 3 | | Example 11 | | |
| Example 3 | Preparative | 32 | Preparative | 8 | None |
| | Example 5 | | Example 11 | | |
| Example 4 | Preparative | 32 | Preparative | 8 | None |
| | Example 7 | | Example 11 | | |
| Example 5 | Preparative | 32 | Preparative | 8 | None |
| | Example 9 | | Example 11 | | |
| Example 6 | Preparative | 32 | Preparative | 8 | None |
| | Example 12 | | Example 11 | | |
| Example 7 | Preparative | 32 | Preparative | 8 | None |
| | Example 14 | | Example 11 | | |
| Comparative | Preparative | 32 | Preparative | 8 | None |
| Example 1 | Example 2 | | Example 11 | | |
| Comparative | Preparative | 32 | Preparative | 8 | None |
| Example 2 | Example 4 | | Example 11 | | |
| Comparative | Preparative | 32 | Preparative | 8 | None |
| Example 3 | Example 6 | | Example 11 | | |
| Comparative | Preparative | 32 | Preparative | 8 | None |
| Example 4 | Example 8 | | Example 11 | | |
| Comparative | Preparative | 32 | Preparative | 8 | None |
| Example 5 | Example 10 | | Example 11 | | |
| Comparative | Preparative | 32 | Preparative | 8 | None |
| Example 6 | Example 13 | | Example 11 | | |
| Comparative | Preparative | 32 | Preparative | 8 | None |
| Example 7 | Example 15 | | Example 11 | | |
| Comparative | Preparative | 32 | Preparative | 8 | Exessive |
| Example 8 | Example 16 | | Example 11 | | bubbles |
| | | | | | presented |

### EXPERIMENTAL EXAMPLE

### Measurement of Adhesiveness Between the Copper Clad and the Polyimide Layer

For the measurement of adhesiveness between the copper clad and the polyimide layer in the copper clad laminate according to the invention, the method was performed as followings.

The copper clad laminates prepared in Examples 1 to 7 and Comparative Examples 1 to 7 were cut to a size of 15 D by 15 D. The test samples were placed in an oven, and heated at 420° C. for 10 seconds. Then, their adhesiveness was measured at room temperature. Even though trying to measure adhesiveness of the copper clad laminate which was prepared in Comparative Example 8, many bubbles were presented on the surface of the cured. Therefore, its adhesiveness could not be measured.

Their adhesiveness was measured by using experimental apparatus such as power driven testing machine (crosshead autographic type, equivalent constant speed drive machine), Thwing Albert sample cutter (Model No, JDC-50), test facilities (Free wheeling rotary drum, sliding plate, reference fixture is 152.4 nm (6 in) wheeling rotary drum) and Solder Pot (heated electrically, its temperature controlled automatically, accommodating 2.25 Kg of SN60 solder and test samples).

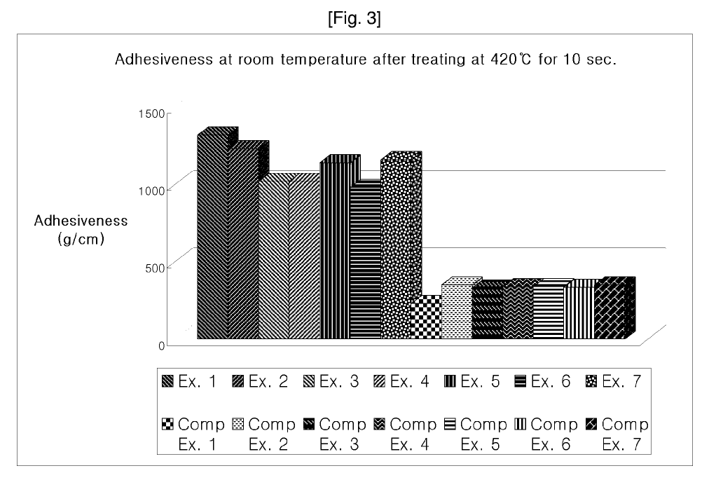

The results of measurement of the adhesiveness are shown in Table 3 and FIG. 3 as follows.

TABLE 3

| | Adhesiveness (g/cm) at room temperature |
|---|---|
| | after treating at 420° C. for 10 seconds |
| Example 1 | 1,320 |
| Example 2 | 1,230 |
| Example 3 | 1,020 |
| Example 4 | 1,020 |
| Example 5 | 1,140 |
| Example 6 | 980 |
| Example 7 | 1,160 |
| Comparative Example 1 | 230 |
| Comparative Example 2 | 350 |
| Comparative Example 3 | 330 |
| Comparative Example 4 | 340 |
| Comparative Example 5 | 340 |
| Comparative Example 6 | 335 |
| Comparative Example 7 | 350 |

As shown in Table 3 and FIG. 3, the copper clad laminates (Examples 1 to 7) according to the invention, comprise 1.5 mol % or more of an azole-based compound having an amine group, based on the total of diamine and dianhydride or 0.5% by weight of an azole-based compound, a polysiloxane-based compound or a polyphosphate-based compound not having an amine group, based on the total weight of solid polyamic acid, upon preparing the polyimide layer. Accordingly, upon tin plating the copper clad at high temperature, delamination between the copper clad and the polyimide layer can be prevented and adhesiveness was improved with 1,000 to 1,400 g/□.

On the other hand, upon preparing the polyimide layer, in the case where the polyimide layer on the copper clad laminates (Comparative Examples 1 to 7) did not comprise an azole-based compound, a polysiloxane-based compound or a polyphosphate-based compound, or contained them in a ratio lower than a specific ratio, their adhesiveness was significantly deteriorated with 200 to 400 g/□.

1. A copper clad laminate for a chip on a film comprising a copper clad and at least one polyimide layer laminated on the copper clad, wherein the polyimide layer in contact with the copper clad comprises at least one additive selected from the group consisting of an azole-based compound, a polysiloxane-based compound, and a polyphosphate-based compound.

2. The copper clad laminate for a chip on a film according to claim 1, wherein the polyimide layer is prepared by reacting at least one diamine selected from the group consisting of para-phenylene diamine (p-PDA), m-phenylene diamine (m-PDA), 4,4′-oxydianiline (4,4′-ODA), 3,4′-oxydianiline (3,4′-ODA), 2,2-bis (4-[4-aminophenoxy]-phenyl) propane (BAPP), 2,2′-dimethyl-4,4′-diamino biphenyl (m-TB-HG), 1,3-bis(4-aminophenoxy)benzene (TPER), 4,4′-diamino benzanilide (DAB A), and 4,4′-bis(4-aminophenoxy)biphenyl (BAPB), with at least one dianhydride selected from the group consisting of pyromellitic dianhydride (PMDA), 3,3′,4,4′-biphenyltetracarboxylic dianhydride (BPDA), 3,3′,4,4′-benzophenonetetracarboxilic dianhydride (BTDA), and 4,4′-oxydiphthalic anhydride (ODPA).

3. The copper clad laminate for a chip on a film according to claim 1, wherein the azole-based compound is at least one compound selected from the group consisting of 3,5-diamino-1,2,4-triazole, 3-amino-1,2,4-triazole, 5-amino-1,2,4-triazole-5-carboxylic acid, 3-amino-5-mercapto-1,2,4-triazole, 5-amino-1H-tetrazole, 3-mercapto-1,2,4-triazole, 5-phenyl-1H-tetrazole, and 2-hydroxy-n-1H-1,2,4-triazole-3-ylbenzamide (ADK).

4. The copper clad laminate for a chip on a film according to claim 1, wherein the azole-based compound having an amine group has a content of 1.5 to 5 mol %, based on the total of diamine and dianhydride.

5. The copper clad laminate for a chip on a film according to claim 1, wherein the azole-based compound not having an amine group has a content of 0.5 to 5% by weight, based on the total weight of solid polyamic acid.

6. The copper clad laminate for a chip on a film according to claim 1, wherein the polysiloxane-based compound is hydroxy terminated poly(dimethylsiloxane) (molecular weight: 500 to 3,000) or hydroxy terminated poly(dimethylsiloxane) (molecular weight: 3,000 to 10,000).

7. The copper clad laminate for a chip on a film according to claim 1, wherein the polyphosphate-based compound is a polyphosphoric acid (H₃PO₄; containing P₂O₅ of 70 to 71% by weight or more in phosphoric acid) or a polyphosphoric acid (H₃PO₄; containing P₂O₅ of 82.5 to 83.5% by weight or more in phosphoric acid).

8. The copper clad laminate for a chip on a film according to claim 1, wherein the polysiloxane-based compound or the polyphosphate-based compound has a content of 0.5 to 5% by weight respectively, based on the total weight of solid polyamic acid.

9. The copper clad laminate for a chip on a film according to claim 1, wherein the polyimide layer is composed of a base layer and a curl control layer, and the base layer is the polyimide layer in contact with the copper clad.

10. The copper clad laminate for a chip on a film according to claim 1, wherein the polyimide layer has a thickness of 30 to 50 □.

11. A method of producing a copper clad laminate for chip on film, comprising the steps of;
1) coating a polyamic acid solution on each or both sides of a copper clad, wherein the polyamic acid solution comprises at least one additive selected from the group consisting of an azole-based compound, a polysiloxane-based compound, and a polyphosphate-based compound, and drying it, and
2) coating a polyamic acid solution on each or both sides of the copper clad dried in the step of 1), wherein the polyamic acid solution does not comprise one or more additive selected from the group consisting of an azole-based compound, a polysiloxane-based compound, and a polyphosphate-based compound, drying it, and then curing it.

12. A printed circuit board comprising the copper clad laminate according to any one of claims 1 to 10.
